(19) United States
(12) Patent Application Publication
(10) Pub. No.: US 2019/0048293 A1
(43) Pub. Date: Feb. 14, 2019

(54) CLEANING SOLUTION AND CLEANING METHOD FOR A SEMICONDUCTOR SUBSTRATE OR DEVICE

(71) Applicant: TOKYO OHKA KOGYO CO., LTD., Kawasaki-shi (JP)

(72) Inventors: Takumi NAMIKI, Kawasaki-shi (JP); Takayuki HARAGUCHI, Hsinchu City (TW); Jen-Chieh SHIH, Hsinchu City (TW)

(21) Appl. No.: 16/079,390

(22) PCT Filed: Mar. 1, 2017
(86) PCT No.: PCT/JP2017/008134

§ 371 Date: Aug. 23, 2018

(30) Foreign Application Priority Data
Mar. 1, 2016 (JP) 2016-039436

(51) Int. Cl. C11D 7/32; C11D 7/50; C11D 11/00; C11D 17/08; H01L 21/02

(52) U.S. Cl. CPC C11D 7/3209; C11D 7/5022; H01L 21/0273; C11D 17/08; H01L 21/0206; C11D 11/0047

(57) ABSTRACT

A cleaning solution and a cleaning method for a semiconductor substrate or device, which has particularly excellent cleaning performance for removing a residue or film including an inorganic substance that contains silicon atoms, and that has a high flash point. The cleaning solution contains a water miscible organic solvent, a quaternary ammonium hydroxide, and water. The water miscible organic solvent is a glycol ether based solvent or an aprotic polar solvent having a flash point of 60° C. or greater. The cleaning method includes using the cleaning solution to clean from the semiconductor substrate or the device a residue or film formed on the semiconductor substrate or adhered to the device, the residue or film including at least one of a resist and an inorganic substance that contains silicon atoms.

### TECHNICAL FIELD

The present invention relates to a cleaning solution and a cleaning method for a semiconductor substrate or device.

### BACKGROUND ART

A semiconductor device include metal wiring, a low dielectric layer, and an insulating layer, or the like, stacked on a semiconductor substrate such as a silicon wafer, and is manufactured by processing each of the above-mentioned layers by a lithography method in which etching is carried out using a resist pattern as a mask. In a resist pattern formation step in the above-mentioned lithography method, a resist pattern is formed by forming resist films corresponding to exposure wavelength, and films such as an anti-reflection film and a sacrificial film provided as a lower layer with respect to the resist films.

Such a resist pattern formation step requires a plurality of cleaning steps including a step of removing an unnecessary coating film attached to one or both of a rear surface and an end of a substrate on which a coating film has been formed; and a step of removing a whole film on a substrate on which a film has been formed on the substrate. Furthermore, residues that derive from the metal wiring and low dielectric layer and are produced during the etching step are removed using a cleaning solution, in order to prevent impediment to a subsequent step and to prevent hindrance to the semiconductor device.

Furthermore, residues or films attached to a device that supplies a substrate with materials for forming the above-mentioned various coating films may clog a pipe, or may have a bad influence on formation of resist patterns or subsequent post process. Consequently, such supply devices need to be subjected to appropriate cleaning process (see, for example, Patent Document 1).

In addition, in a step of manufacturing a semiconductor device, from the viewpoint of yield improvement, such as rework, and reduction of environmental loading, such as reuse, a film formed on the substrate and residues thereof are removed with a cleaning solution.
Patent Document 1: Japanese Unexamined Patent Application, Publication No. 2006-332082

### DISCLOSURE OF THE INVENTION

### Problems to be Solved by the Invention

However, a conventional cleaning solution may not provide sufficient cleaning performance. For example, a film including an inorganic substance that contains a silicon atom (hereinafter, also referred to as a “silicon atom-containing inorganic substance”), which is formed as a sacrificial film, or residues of the film is not easily removed, and therefore, a cleaning solution is required to have higher cleaning performance. In addition, in order to facilitate handling including storage or management of products, a flash point of a cleaning solution is preferably higher than that of a conventional cleaning solution.

The present invention has been made considering the above situations, and has an object to provide a cleaning solution and a cleaning method for a semiconductor substrate or device, wherein the cleaning solution has excellent cleaning performance for removing, in particular, residues or films including a silicon atom-containing inorganic substance, and has a high flash point.

### Means for Solving the Problems

The present inventors have found that in a cleaning solution containing a water-soluble organic solvent, quaternary ammonium hydroxide, and water, when a glycol ether solvent or an aprotic polar solvent having a flash point of 60° C. or more is used as the water-soluble organic solvent, the cleaning solution is particularly excellent in removing performance for removing residues or films including a silicon atom-containing inorganic substance, and has a high flash point, and the present inventors have completed the present invention. Specifically, the present invention provides the followings.

A first aspect of the present invention is a cleaning solution for a semiconductor substrate or device, the cleaning solution containing a water-soluble organic solvent, quaternary ammonium hydroxide, and water, wherein the water-soluble organic solvent is a glycol ether solvent or an aprotic polar solvent having a flash point of 60° C. or more.

A second aspect of the present invention is a cleaning method including cleaning a residue or a film from a semiconductor substrate or device, using a cleaning solution according to the first aspect of the present invention, wherein the residue or the film is formed on the semiconductor substrate or attached to the device and includes at least one selected from the group consisting of a resist and a silicon atom-containing inorganic substance.

### Effects of the Invention

The present invention can provide a cleaning solution and a cleaning method for a semiconductor substrate or device, wherein the cleaning solution has excellent cleaning performance for removing, in particular, a residue or a film including a silicon atom-containing inorganic substance, and has a high flash point. Hereinafter, “a residue or a film including a silicon atom-containing inorganic substance” may be generically called an “inorganic material film”.

In the present invention, the “residue or film including a silicon atom-containing inorganic substance” may be a residue or a film, which contains a silicon atom-containing inorganic substance as a main component, but may be a residue or a film including only a silicon atom-containing inorganic substance. The cleaning solution of the present invention can remove the latter one more effectively.

### PREFERRED MODE FOR CARRYING OUT THE INVENTION

Hereinafter, embodiments of the present invention will be explained in detail.

### <Cleaning Solution>

A cleaning solution of this embodiment is a cleaning solution containing a water-soluble organic solvent, quaternary ammonium hydroxide, and water. The water-soluble organic solvent is a glycol ether solvent or an aprotic polar solvent having a flash point of 60° C. or more. Such a cleaning solution is suitable as a cleaning solution for a semiconductor substrate or device.

The cleaning solution of this embodiment has a high flash point, and can effectively remove a residue or a film that is present on a semiconductor substrate and includes a silicon atom-containing inorganic substance, or a residue or a film including a silicon atom-containing inorganic substance attached to a device (including a pipe etc.). Preferably, the cleaning solution further can effectively remove a residue or a film including a resist (hereinafter, the “residue or film including a resist” may be generically called a “resist film”). Such a cleaning solution is suitable for a case where generality that brings applicability to a plurality of different objects to be cleaned is desired. In this embodiment, the “residue or film including a resist” may be a residue or a film that contains a resist as a main component.

### [Water-Soluble Organic Solvent]

A water-soluble organic solvent to be used for a cleaning solution of this embodiment is a glycol ether solvent or an aprotic polar solvent.

### (Glycol Ether Solvent)

In this specification, a glycol ether solvent is a solvent in which at least one of two hydroxyl groups of glycol forms ether. Glycol is a compound in which one each of hydroxy group is substituted by two carbon atoms of aliphatic hydrocarbon. The aliphatic hydrocarbon may be any of a chain aliphatic hydrocarbon or a cyclic aliphatic hydrocarbon, but a chain aliphatic hydrocarbon is preferable. The glycol ether solvent is specifically a solvent that is glycol ether represented by the following general formula. R^{S1}—O—(R^{S2}—O)ₙ—R^{S3}

(In the above general formula, R^{S1} and R^{S3} each independently represents a hydrogen atom, or an alkyl group having 1 to 6 carbon atoms, R^{S2} represents an alkylene group having 1 to 6 carbon atoms, and n is an integer of 1 to 5. However, at least one of R^{S1} and R^{S3} is an alkyl group having 1 to 6 carbon atoms.)

As the glycol ether solvent, a solvent in which at least one of two hydroxyl groups of glycol forms ether, and, specifically, a solvent in which R^{S1} or R^{S3} in the above-mentioned formula is glycol monoalkyl ether that is an alkyl group having 1 to 6 carbon atoms is preferable. Examples of such glycol monoalkyl ethers include 3-methoxy-3-methyl-1-butanol (MMB), diisopropylene glycol monomethyl ether (DPM), methyl diglycol (MDG), ethyl diglycol (EDG), and butyl diglycol (BDG), ethylene glycol monobutyl ether (ELBE), and the like. Among them, because of being excellent in cleaning performance with respect to both a resist film and an inorganic material film, 3-methoxy-3-methyl-1-butanol (MMB), diisopropylene glycol monomethyl ether (DPM), ethyl diglycol (EDG), and butyl diglycol (BDG) are preferable, and diisopropylene glycol monomethyl ether (DPM), and ethyl diglycol (EDG) are more preferable. Furthermore, because a cleaning solution having good cleaning performance and/or flash point is obtained, and the range of content (concentration) of the water-soluble organic solvent is wide, diisopropylene glycol monomethyl ether (DPM) is particularly preferable.

### (Aprotic Polar Solvent)

An aprotic polar solvent to be used in this embodiment is a solvent that does not have proton donor ability and that has polarity. Such an aprotic polar solvent is preferably one or more selected from a sulfoxide compound such as dimethyl sulfoxide (DMSO); a sulfolane compound such as sulfolane; an amide compound such as N,N-dimethyl acetamide (DMAc); a lactam compound such as N-methyl-2-pyrrolidone (NMP) and N-ethyl-2-pyrrolidone; a lactone compound such as β-propiolactone, γ-butyrolactone (GBL), and s-caprolactone; and an imidazolidinone compound such as 1,3-dimethyl-2-imidazolidinone (DMI), and the like. Among them, in particular, because of being excellent in removing performance with respect to both a resist film and an inorganic material film, a sulfoxide compound, a sulfolane compound, and a lactam compound are preferable. Among them, dimethyl sulfoxide (DMSO), sulfolane, and N-methyl-2-pyrrolidone (NMP) are preferable, a dimethyl sulfoxide (DMSO), an N-methyl-2-pyrrolidone (NMP) are more preferable. Furthermore, because a concentration range of the water-soluble organic solvent capable of achieving a cleaning solution having a good cleaning performance is wide, N-methyl-2-pyrrolidone (NMP) is further preferable.

### (Flash Point, LogP Value)

A water-soluble organic solvent to be used in the cleaning solution of this embodiment has a flash point of 60° C. or more, and preferably 60 to 150° C. The flash point of 60° C. or more facilitates handling in storage, management and the like of product. The flash point is preferably high in terms of the handling property. However, since in a cleaning step, drying performance to promptly dry for a short time may be required, the flash point is preferably 150° C. or less. Examples of such a water-soluble organic solvent include 3-methoxy-3-methyl-1-butanol (MMB) having a flash point of 67° C., diisopropylene glycol monomethyl ether (DPM) having a flash point of 76.5° C., methyl diglycol (MDG) having a flash point of 105° C., ethyl diglycol (EDG) having a flash point of 97° C., butyl diglycol (BDG) having a flash point of 120° C., N-methyl-2-pyrrolidone (NMP) having a flash point of 86° C., dimethyl sulfoxide (DMSO) having a flash point of 95° C., and the like.

The LogP value of the water-soluble organic solvent is preferably in the range from −1.0 to 0.8, more preferably in the range from −0.7 to 0.7, and further preferably in the range from −0.5 to 0.5. Examples of such a water-soluble organic solvent include 3-methoxy-3-methyl-1-butanol (MMB) having a LogP value of 0.113, diisopropylene glycol monomethyl ether (DPM) having a LogP value of 0.231, methyl diglycol (MDG) having a LogP value of −0.595, ethyl diglycol (EDG) having a LogP value of −0.252, butyl diglycol (BDG) having a LogP value of 0.612, N-methyl-2-pyrrolidone (NMP) having a LogP value of −0.397, dimethyl sulfoxide (DMSO) having a LogP value of −0.681, and the like. In particular, it is preferable to use water-soluble organic solvent having a LogP value of −0.5 to 0.5, for example, diisopropylene glycol monomethyl ether (DPM), ethyl diglycol (EDG), N-methyl-2-pyrrolidone (NMP), and the like, because both a resist film and an inorganic material film can be effectively removed.

The LogP value refers to as octanol/water partition coefficient, and can be computed by calculation using parameter by Ghose, Pritchett, Crippen et al. (see J. Comp. Chem., 9, 80 (1998)). This calculation can be carried out by using software such as CAChe 6.1 (FUJITSU Ltd.).

Among them, the water-soluble organic solvent preferably has a flash point of 70 to 100° C. and a LogP value of −0.5 or more. For example, diisopropylene glycol monomethyl ether (DPM) having a flash point of 76.5° C. and a LogP value of 0.231, ethyl diglycol (EDG) having a flash point of 97° C. and a LogP value of 0.252, and N-methyl-2-pyrrolidone (NMP) having a flash point of 86° C. and a LogP value of −0.397 are preferable. Use of these water-soluble organic solvents can increase the flash point of the cleaning solution, and can effectively remove both a resist film and an inorganic material film. Moreover, the water-soluble organic solvent can be contained in a relatively wide range of concentration.

### (Content)

The content of the water-soluble organic solvent is preferably 50% by mass, more preferably 50 to 90 mass %, further preferably 55 to 85% by mass, and further more preferably 60 to 80% by mass with respect to the total amount of the cleaning solution. With such a content, the flash point of the cleaning solution can be increased, and an inorganic material film, further preferably, a resist film can be effectively removed.

Specifically, when the flash point is 60° C. or more and less than 70° C., the water-soluble organic solvent is preferably 75% by mass or less with respect to the mass of the cleaning solution. In such a range, the water-soluble organic solvent may be 50% by mass or more, preferably, 55% by mass or more, more preferably, 60% by mass or more, further preferably, 65% by mass or more, and particularly preferably, about 70% by mass. Examples of such a water-soluble organic solvent include 3-methoxy-3-methyl-1-butanol (MMB) having a flash point of 67° C., and the like. Even when a water-soluble organic solvent which tends to lower a flash point of a cleaning solution as the content is relatively increased, the content in the above-mentioned range is preferable because it suppresses the lowering of the flash point of the cleaning solution, thus improving the handling property.

The water-soluble organic solvent is preferably 65% by mass or more, more preferably 65 to 85% by mass, and further preferably 70 to 80% by mass with respect to the mass of the cleaning solution, when the LogP value is less than −0.5. Examples of such a water-soluble organic solvent include dimethyl sulfoxide (DMSO) having a LogP value of −0.681, methyl diglycol (MDG) having a LogP value of −0.595, and the like. When the water-soluble organic solvent is dimethyl sulfoxide (DMSO), the water-soluble organic solvent is more preferably 75 to 85% by mass and particularly preferably about 80% by mass, with respect to the mass of the cleaning solution. Even when a water-soluble organic solvent whose LogP value is low as in the above-mentioned range, it is preferable that the content is in the above-mentioned range, in particular, from the viewpoint that the cleaning property of a resist film is improved.

When the LogP value is −0.5 to −0.2, and particularly −0.4 to −0.25, the water-soluble organic solvent is preferably 65% by mass or more, more preferably 65 to 85% by mass, and further preferably 70 to 80% by mass with respect to the mass of the cleaning solution. Examples of such a water-soluble organic solvent include N-methyl-2-pyrrolidone (NMP) having a LogP value of −0.397, ethyl diglycol (EDG) having a LogP value of −0.252, and the like. Even when the water-soluble organic solvent having such a low LogP value as in the above-mentioned range is used, it is preferable that the content is in the above-mentioned range, particularly from the viewpoint that the cleaning property of the inorganic material film can be improved.

The cleaning solution of this embodiment preferably contains, as a water-soluble organic solvent, at least one selected from the group consisting of 55 to 75% by mass and particularly 60 to 70% by mass of 3-methoxy-3-methyl-1-butanol (MMB), 55 to 85% by mass and particularly 60 to 80% by mass of diisopropylene glycol monomethyl ether (DPM), 55 to 85% by mass and particularly 60 to 80% by mass of N-methyl-pyrrolidone (NMP), 60 to 85% by mass, 65 to 85% by mass, and particularly 70 to 80% by mass of dimethyl sulfoxide (DMSO), 55 to 85% by mass, 65 to 85% by mass, and particularly 70 to 80% by mass of methyl diglycol (MDG), 55 to 85% by mass and particularly 60 to 80% by mass ethyl diglycol (EDG), 55 to 85% by mass and particularly 60 to 80% by mass of butyl diglycol (BDG), as well as 65 to 85% by mass, 75 to 85% by mass, and particularly 80% by mass of sulfolane, with respect to the mass of the cleaning solution. It is more preferable that the water-soluble organic solvent is one selected from the above-mentioned group.

Among them, as a water-soluble organic solvent, at least one selected from the group consisting of 65 to 75% by mass, and particularly 70% by mass of 3-methoxy-3-methyl-1-butanol (MMB), 55 to 85% by mass, and particularly 60 to 80% by mass of diisopropylene glycol monomethyl ether (DPM), 65 to 85% by mass, and particularly 70 to 80% by mass of N-methyl-pyrrolidone (NMP), 65 to 85% by mass, and particularly 70 to 80% by mass of ethyl diglycol (EDG), as well as 75 to 85% by mass, and particularly 80% by mass of butyl diglycol (BDG), with respect to the mass of the cleaning solution, is preferably contained. It is more preferable that the water-soluble organic solvent is one selected from the above-mentioned group. Note here that the water-soluble organic solvent may be a single one type, or a mixture of a plurality of types. However, single one type can effectively remove a resist film and an inorganic material film when single one type is contained in the above-mentioned range of content.

### [Water]

As water, purified water, deionized water, ion exchanged water, or the like, can be preferably used. The content of water is preferably 5 to 50% by mass, and more preferably 10 to 35% by mass with respect to the total amount of the cleaning solution. The content of water in above-mentioned range can facilitate handling. Needless to say, the remaining amount other than the water-soluble organic solvent and quaternary ammonium hydroxide, as well as diol and other components, which are contained as necessary, may be water.

### [Quaternary Ammonium Hydroxide]

As quaternary ammonium hydroxide, a compound represented by the following formula (1) is preferably used. By blending quaternary ammonium hydroxide, it is possible to effectively remove an inorganic material film, and preferably, further a resist film.

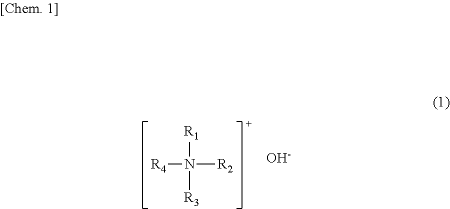

(In the above general formula, R¹, R², R³, and R⁴ each independently represents an alkyl group or a hydroxyl alkyl group having 1 to 6 carbon atoms.)

Specific examples of the quaternary ammonium hydroxide include tetramethyl ammonium hydroxide (TMAH), tetraethyl ammonium hydroxide, tetrapropyl ammonium hydroxide, tetrabutyl ammonium hydroxide, tetrapentyl ammonium hydroxide, monomethyl triple ammonium hydroxide, trimethyl ethyl ammonium hydroxide, (2-hydroxyethyl)trimethyl ammonium hydroxide, (2-hydroxyethyl)triethyl ammonium hydroxide, (2-hydroxyethyl)tripropyl ammonium hydroxide, (1-hydroxypropyl)trimethyl ammonium hydroxide, and the like. Among them, TMAH, tetraethyl ammonium hydroxide, tetrapropyl ammonium hydroxide, tetrabutyl ammonium hydroxide, monomethyl triple ammonium hydroxide, (2-hydroxyethyl)trimethyl ammonium hydroxide, and the like, is preferable because of easiness in availability and being excellent in safety. One type or two or more types of the quaternary ammonium hydroxide can be used.

The content of the quaternary ammonium hydroxide is preferably 0.1 to 20% by mass, more preferably 0.3 to 15% by mass, further preferably 0.5 to 10% by mass, and further more preferably 1 to 3% by mass, with respect to the total amount of the cleaning solution. When the content of the quaternary ammonium hydroxide is in the above-mentioned range, while the good solubility of an inorganic material film, preferably further a resist film, is maintained, corrosion of metal wiring etc. to the other materials can be prevented.

### [Other Components]

The cleaning solution of this embodiment may include other components, such as a solvent other than the above-mentioned water-soluble organic solvents, and a surfactant, within a range where the advantageous effects of the present invention are not impaired. As the above-mentioned solvent other than the above-mentioned water-soluble organic solvents, a solvent having a flash point of 60° C. or more is preferable, and examples thereof include polyhydric alcohol such as ethylene glycol, propylene glycol, butylene glycol, and glycerine, and the like. Among them, diol having two hydroxyl groups is preferable. Among them, propylene glycol is preferable from the viewpoint of handling property, and viscosity. The content of the solvent other than the water-soluble organic solvents mentioned above is preferably more than 0% by mass and 20% by mass or less, more preferably 1 to 15% by mass, further preferably 2 to 10% by mass, and further more preferably 3 to 8% by mass, with respect to the total amount of the cleaning solution. Such a content enables handling property, viscosity, and the like, of the cleaning solution to be adjusted as needed. The cleaning solution of this embodiment may include, for example, 35% by mass or less, specifically, in the above-mentioned range of content, of polyhydric alcohol having three or more hydroxyl groups, for example, glycerine. However, from the viewpoint of maintaining the cleaning performance, the polyhydric alcohol may not be contained. The surfactant is not particularly limited, and examples thereof include a nonionic surfactant, an anionic surfactant, a cationic surfactant, an amphoteric surfactant, and the like.

### <Cleaning Method>

A cleaning method using a cleaning solution of the present invention is one of the present invention. A cleaning method of the present invention includes cleaning or removing a residue or a film from a semiconductor substrate or device, using a cleaning solution according to the first aspect of the present invention, wherein the residue or the film is formed on the semiconductor substrate or attached to the device and includes at least one selected from the group consisting of a resist and a silicon atom-containing inorganic substance.

As the residue or the film, for example, all or a part of various films formed in manufacturing a semiconductor substrate, or residues remaining on a semiconductor substrate or the like after the film has been removed, and the like. The device is not particularly limited, and devices having a portion on which the above-mentioned residue or film is easily attached can be suitably used. Examples thereof include the below-mentioned chemical solution supply device for forming various coating films in manufacturing a semiconductor substrate. Hereinafter, a chemical solution supply device is described as an example of the device. Furthermore, hereinafter, a semiconductor substrate may be simply abbreviated as a “substrate”.

The cleaning solution of this embodiment is applicable to a plurality of cleaning purposes in which objects to be cleaned are different, for example, (I) a step of removing unnecessary coating films attached to one or both of a rear surface and an end of a substrate on which a coating film has been formed, (II) a step of removing a whole coating film that is present on a substrate on which a coating film has been formed, (III) a step of cleaning various substrates such as a substrate before a coating liquid for forming a coating film is applied, or the like, (IV) a step of cleaning a chemical solution supply device for forming various coating films. In any cases, high cleaning performance is shown.

The above (I) a step of removing unnecessary coating films attached to one or both of a rear surface and an end of a substrate on which a coating film has been formed is specifically as follows.

When a coating film such as a resist, an anti-reflection film, a protective film, or the like, is formed on a substrate, the coating film is formed on the substrate by, for example, a spin coating method using a spinner. When a coating film is applied on a substrate in this way, since this coating film is diffusion applied in a radial direction by centrifugal force. Consequently, a film thickness of the end of the substrate is larger than that of the center of the substrate, and furthermore, the coating film may also reach the rear surface of the substrate.

Thus, unnecessary coating films attached to one or both of the rear surface and the end of the substrate are brought into contact with the cleaning solution of this embodiment so as to be cleaned and removed. Use of the cleaning solution of this embodiment makes it possible to remove unnecessary coating films of at least one of the end and the rear surface of the substrate efficiently for a short time.

Specific methods for bringing the unnecessary coating film into contact with the cleaning solution of this embodiment so as to be cleaned and removed is not particularly limited, and the well-known methods can be employed.

Examples of such a method include a method of dropping or spraying a cleaning solution to an end or a rear surface of a substrate by using a cleaning solution supply nozzle while rotating the substrate. In this case, a supply amount of the cleaning solution from the nozzle is appropriately changed depending on the types or film thicknesses and the like of coating films such as resist, but it is usually selected from a range from 3 to 50 ml/min. Alternatively, a method of inserting an end of a substrate into a storage portion filled with the cleaning solution in advance from the horizontal direction, and soaking the end of the substrate in the cleaning solution inside the storage portion for a desired time, and the like. However, the method is not limited to these exemplified methods alone.

The above (II) step of removing a whole coating film that is present on a substrate on which a coating film has been formed is specifically as follows.

A coating film applied on a substrate is hardened by drying by heating, but in an actual working step, for example, when failures occur in formation of a coating film, subsequent processing steps are not continued, and the whole coating film having the failures is brought into contact with the cleaning solution of this embodiment to be cleaned and removed. In such a case, the cleaning solution of this embodiment can be used. Such a step is generally called a rework process, and a method for such a rework process is not particularly limited, and well-known methods can be used.

The above (III) step of cleaning a substrate before a coating film forming material is applied is specifically as follows.

The step is carried out by dropping the cleaning solution of this embodiment onto the substrate before a coating film is formed on the substrate. Such a step is called a pre-wet process. The pre-wet process is also a process for reducing a use amount of resist, but in the present invention, this step is described as one of cleaning steps for a substrate. A method of such a pre-wet process is not particularly limited, and well-known methods can be employed.

The above (IV) step of cleaning a chemical solution supply device for forming various coating films is specifically as follows.

The chemical solution supply device for forming the various coating films includes a pipe, a chemical solution application nozzle, a coater cup, and the like, and can be effectively used for cleaning and removing chemical solution attached and solidified to such a chemical solution supply device by using the cleaning solution of this embodiment.

As the method for cleaning the pipe mentioned above, for example, a chemical solution is completely exhausted from the inside of the pipe of the chemical solution supply device, and the pipe is made empty. Then, the cleaning solution of this embodiment is poured and filled into the pipe, and allowed to stand for a predetermined time. After the predetermined time, while the cleaning solution is being discharged from the pipe, or after the cleaning solution is discharged, the chemical solution for forming a coating film is poured into and allowed to flow in the pipe. Thereafter, supply of the chemical solution onto the substrate or discharge of the chemical solution is started.

The cleaning solution of this embodiment is widely applicable to the pipe in which materials for forming various coating films are allowed to flow, has excellent compatibility and does not have reactivity. Therefore, the cleaning solution has excellent effects, for example, heat generation and gas generation do not occur, property abnormality of liquid, for example, separation and cloudiness inside the pipe, is not observed, and foreign substances in the liquid are not increased, and the like.

In particular, even when a residue or a film is attached to the inside of a pipe due to long-time use, the cleaning solution of this embodiment enables the residue or film to be dissolved and a cause of generation of particles to be completely removed. Furthermore, in re-starting of supply of a chemical solution, chemical solution supply operation can be started only by carrying out emptying and flowing while the cleaning solution is exhausted or after exhausted.

Furthermore, as a method for cleaning the above-mentioned chemical solution application nozzle, coating film residues attached to the application nozzle portion of the chemical solution supply device are brought into contact with the cleaning solution of this embodiment by a well-known method so as to clean and remove the attached chemical solution. In addition, when the application nozzle is not used for a long time, a tip end of the application nozzle is in a dispense state in a solvent atmosphere. The cleaning solution of this embodiment is useful as a dispense solution. However, the method is not limited to these methods alone.

Furthermore, as a method for cleaning the above-mentioned coater cup, coating film residues attached to the coater cup inside the chemical solution supply device are brought into contact with the cleaning solution of this embodiment by a well-known method, so that the attached chemical solution can be cleaned and removed. However, the method is not limited to these methods alone.

Furthermore, examples of the coating film that is a subject to removal by using the cleaning solution of this embodiment include resist films corresponding to various exposure wavelength such as g-ray, i-ray, KrF excimer laser, ArF excimer laser, EUV, etc., and an anti-reflection film and a sacrificial film made of an inorganic material film such as a silicon hard mask containing a silicon atom, provided as a lower layer with respect to these resist films, and a protective film etc. provided as an upper layer with respect to the resist. For such coating films, well-known films can be used. In particular, in a liquid immersion lithography method, a film provided as a lower layer with respect to a resist, a resist film, and further, a protective film, are sequentially laminated on a substrate. Use of the same cleaning solution can be used to all these material-system is a large merit.

Note here that examples of the resist film include material including novolac resin, styrene resin, acrylic resin, and the like, as a substrate resin component. Examples of the anti-reflection film provided as a lower layer with respect to the resist film include material including acrylic resin having a light-absorbing substituent. Furthermore, examples of the sacrificial film provided as a lower layer with respect to the resist film, and examples of the protective film provided as an upper layer with respect to the resist film include material including alkali-soluble resin including a fluorine atom-containing polymer, are generally used, respectively.

Furthermore, in the cleaning step using the cleaning solution of this embodiment, cleaning performance capable of cleaning and removing a subject to be cleaned efficiently for a short time is required. Time required for the cleaning process varies depending on each cleaning step, but usually, performance capable of achieving cleaning for 1 to 60 seconds is required.

Furthermore, similarly, for the drying performance, performance capable of drying for a short time is required, and, usually, performance capable of drying for 5 to 60 seconds is required.

In addition, basic properties such as property of not having an adverse effect on a shape of a remaining film to be used for the subsequent post step are required together.

The cleaning solution of this embodiment has generality that can comprehensively cover a plurality of different film materials for forming various coating films used for a lithography step or a plurality of cleaning applications in which objects to be cleaned are different; has basic properties of cleaning solution, including cleaning performance capable of cleaning and removing a subject to be cleaned efficiently for a short time, drying performance of drying promptly for a short time, and property of not having an adverse effect on a shape of a remaining film to be used for the subsequent post step; and further can satisfy various properties, such as having a high flash point and easy handling, further being inexpensive, and being supplied stably.

Hereinafter, the present invention will be explained in more detail by way of Examples, but the present invention is not limited to the following Examples.

### EXAMPLES

### (Preparation of Cleaning Solution)

Based on compositions and blending amounts shown in the following Tables 1 to 3, a cleaning solution was prepared. Note here that for agents, commercially available agents were used. In addition, numerical values in Tables shown in a unit of % by mass.

TABLE 1

| | Example | | | | | | | | | | |
|---|---|---|---|---|---|---|---|---|---|---|---|
| | 1 | 2 | 3 | 4 | 5 | 6 | 7 | 8 | 9 | 10 | 11 |
| MMB | 60 | 70 | — | — | — | — | — | — | — | — | — |
| DPM | — | — | 60 | 70 | 80 | — | — | — | — | — | — |
| NMP | — | — | — | — | — | 60 | 70 | 80 | — | — | — |
| DMSO | — | — | — | — | — | — | — | — | 60 | 70 | 80 |
| EDG | — | — | — | — | — | — | — | — | — | — | — |
| MDG | — | — | — | — | — | — | — | — | — | — | — |
| BDG | — | — | — | — | — | — | — | — | — | — | — |
| Sulfolane | — | — | — | — | — | — | — | — | — | — | — |
| TMAH | 2 | 2 | 2 | 2 | 2 | 2 | 2 | 2 | 2 | 2 | 2 |
| PG | 5 | 5 | 5 | 5 | 5 | 5 | 5 | 5 | 5 | 5 | 5 |
| Pure water | 33 | 23 | 33 | 23 | 13 | 33 | 23 | 13 | 33 | 23 | 13 |
| Si-HM | Good | Very | Very | Very | Very | Good | Very | Very | Good | Good | Very |
| | | good | good | good | good | | good | good | | | good |
| PR | Very | Very | Very | Very | Very | Very | Very | Very | Bad | Good | Good |
| | good | good | good | good | good | good | good | good | | | |
| Flash point | Absent | Absent | Absent | Absent | Absent | Absent | Absent | Absent | Absent | Absent | Absent |

TABLE 2

| | Example | | | | | | | | | | |
|---|---|---|---|---|---|---|---|---|---|---|---|
| | 12 | 13 | 14 | 15 | 16 | 17 | 18 | 19 | 20 | 21 | 22 |
| MMB | — | — | — | — | — | — | — | — | — | — | — |
| DPM | — | — | — | — | — | — | — | — | — | — | — |
| NMP | — | — | — | — | — | — | — | — | — | — | — |
| DMSO | — | — | — | — | — | — | — | — | — | — | — |
| EDG | 60 | 70 | 80 | — | — | — | — | — | — | — | — |
| MDG | — | — | — | 60 | 70 | 80 | — | — | — | — | — |
| BDG | — | — | — | — | — | — | 60 | 70 | 80 | — | — |
| Sulfolane | — | — | — | — | — | — | — | — | — | 70 | 80 |
| TMAH | 2 | 2 | 2 | 2 | 2 | 2 | 2 | 2 | 2 | 2 | 2 |
| PG | 5 | 5 | 5 | 5 | 5 | 5 | 5 | 5 | 5 | 5 | 5 |
| Pure water | 33 | 23 | 13 | 33 | 23 | 13 | 33 | 23 | 13 | 23 | 13 |
| Si-HM | Good | Very | Very | Good | Good | Good | Good | Good | Very | Good | Good |
| | | good | good | | | | | | good | | |
| PR | Good | Very | Very | Bad | Good | Good | Good | Very | Very | Bad | Good |
| | | good | good | | | | | good | good | | |
| Flash point | Absent | Absent | Absent | Absent | Absent | Absent | Absent | Absent | Absent | Absent | Absent |

TABLE 3

| | Comparative example | | | | | | | | | | |
|---|---|---|---|---|---|---|---|---|---|---|---|
| | 1 | 2 | 3 | 4 | 5 | 6 | 7 | 8 | 9 | 10 | 11 |
| PGME | 60 | 70 | 80 | — | — | — | 70 | — | — | — | — |
| PGMEA | — | — | — | 60 | 70 | 80 | 30 | — | — | — | — |
| GBL | — | — | — | — | — | — | — | 95 | — | — | — |
| Anisole | — | — | — | — | — | — | — | 5 | — | — | — |
| Glycerine | — | — | — | — | — | — | — | — | 60 | 70 | 80 |
| TMAH | 2 | 2 | 2 | 2 | 2 | 2 | — | — | 2 | 2 | 2 |
| PG | 5 | 5 | 5 | 5 | 5 | 5 | — | — | 5 | 5 | 5 |
| Pure water | 33 | 23 | 13 | 33 | 23 | 13 | — | — | 33 | 23 | 13 |
| Si-HM | Good | Very | Very | * | * | * | Good | Good | Bad | Bad | Bad |
| | | good | good | | | | | | | | |
| PR | Very | Very | Very | * | * | * | Very | Very | Bad | Bad | Bad |
| | good | good | good | | | | good | good | | | |
| Flash point | Present | Present | Present | * | * | * | Present | Present | Absent | Absent | Absent |

Abbreviated names of compositions, flash points, and LogP values in the above Tables are as follows.

MMB: 3-methoxy-3-methyl-1-butanol, flash point: 67° C., LogP value: 0.113
DPM: diisopropylene glycol monomethyl ether, flash point: 76.5° C., LogP value: 0.231
NMP: N-methyl-2-pyrrolidone, flash point: 86° C., LogP value: −0.397
DMSO: dimethyl sulfoxide, flash point: 95° C., LogP value: −0.681
EDG: ethyl diglycol, flash point: 97° C., LogP value: −0.252
MDG: methyl diglycol, flash point: 105° C., LogP value: −0.595
BDG: butyl diglycol, flash point: 120° C., LogP value: 0.612
Sulfolane: flash point: 165° C., LogP value: −0.165
TMAH: tetraethyl ammonium hydroxide: LogP value: −2.47
PG: propylene glycol: flash point: 90° C., LogP value: −1.4
PGME: propylene glycol monomethyl ether, flash point: 32° C., LogP value: −0.017
PGMEA: propylene glycol monomethyl ether acetate, flash point: 48.5° C., LogP value: 0.800
GBL: γ-butyrolactone, flash point: 98° C., LogP value: −0.57
Anisole: flash point: 43° C., Log value: 2.11
Glycerine: flash point: 160° C., LogP value: −1.081

### (Cleaning Property of Resist Film)

TArF-P6111 (manufactured by TOKYO OHKA KOGYO CO LTD.), which was an ArF resist material including acrylic resin as a base material resin, was applied onto a silicon wafer and heated at 180° C. for 60 seconds so as to form a resist film having a film thickness of 350 nm. Wafer provided with the resist film was soaked in the cleaning solutions shown in Tables 1 to 3 at 40° C. for one minute, then rinsed with purified water at 25° C. for 60 seconds. Cleaning states of resist films by these processes were evaluated according to the following criteria. The results are shown in Tables 1 to 3. Note here that in Tables, the cleaning properties of the resist films are shown in a row indicated with “PR”.

Very good: Film peelability was good, and film could be completely removed.
Good: Film peelability was observed, and residual film was almost removed.
Bad: Film peelability was not observed, and residual film was observed.
*: Cloudiness occurred, and use as cleaning solution was impossible.

(Cleaning Property of Inorganic Material Film)

A mixture obtained by adding 100 parts by mass of resin represented by the following formula (mass average molecular weight: 9400), 0.3 parts by mass of hexadecyl trimethyl ammonium acetate, 0.75 parts by mass of malonic acid to a mixed solvent of PGMEA/ethyl lactate (EL)=6/4 (volume ratio), and adjusting the polymer solid concentration of resin to 2.5% by mass was applied onto a silicon wafer, heated at 100° C. for one minute, and then heated at 400° C. for 30 minutes so as to form an inorganic material film having a film thickness of 30 nm. The wafer on which the inorganic material film had been formed was soaked in the cleaning solutions shown in Tables 1 to 3 at 40° C. for five minutes, followed by rinsing with purified water at 25° C. for 60 seconds. Cleaning states of the inorganic material film by these processes were evaluated according to the following criteria. The results are shown in Tables 1 to 3. Note here that in Tables, the cleaning property of the inorganic material film is shown in a row indicated with “Si-HM”.

Very good: Film peelability was good, and film was completely removed.
Good: Film peelability was observed, and residual film (residue) was almost removed.
Bad: Film peelability was not observed, and residual film (residue) was observed.
*: Cloudiness occurred, and use as cleaning solution was impossible.

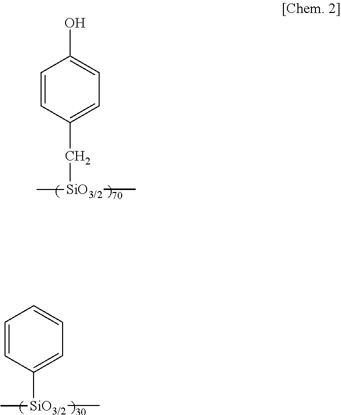

(Presence or Absence of Flash Point)

A flash point under 1 atm was measured by a tag closed tester at a liquid temperature of 80° C. or less, and by a Cleveland Open Cup tester at a liquid temperature of more than 80° C. In this Examples, a case where a flash point could be measured by a Cleveland Open Cup tester was evaluated as “present” and a case where a flash point could not be measured was evaluated as “absent”.

As is apparent from Tables 1 to 3, as the water-soluble organic solvent, Examples 1 to 22 in which 3-methoxy-3-methyl-1-butanol (MMB), diisopropylene glycol monomethyl ether (DPM), N-methyl-2-pyrrolidone (NMP), dimethyl sulfoxide (DMSO), methyl diglycol (MDG), ethyl diglycol (EDG), butyl diglycol (BDG), or sulfolane was used, a flash point was absent, demonstrating that the inorganic material film can be cleaned. In particular, in Examples 1 to 8, 12 to 14, and 18 to 20 in which 3-methoxy-3-methyl-1-butanol (MMB), diisopropylene glycol monomethyl ether (DPM), N-methyl-2-pyrrolidone (NMP), ethyl diglycol (EDG), and butyl diglycol (BDG) were used as the water-soluble organic solvent, demonstrating that both the resist film and the inorganic material film were excellent in cleaning performance. However, from the results of Examples 9 to 11 in which dimethyl sulfoxide (DMSO) was used, or Examples 15 to 17 in which methyl diglycol (MDG) was used, it is shown that in order to enhance the cleaning performance with respect to the resist films, the contents of these water-soluble organic solvents were preferably 65 to 85% by mass, and particularly preferably 70 to 80% by mass. Furthermore, from the results of Examples 21 and 22 in which sulfolane was used, when sulfolane is used as a water-soluble organic solvent, it is shown that the content is preferably 75 to 85% by mass, and particularly preferably about 80% by mass.

On the other hand, in Comparative Examples 1 to 3 in which propylene glycol monomethyl ether (PGME) was used, Comparative Example 7 in which a mixed solvent of propylene glycol monomethyl ether (PGME) and propylene glycol monomethyl ether acetate (PGMEA) was used, and Comparative Example 8 in which a mixed solvent of γ-butyrolactone (GBL) and anisole was used, the cleaning property with respect to a resist film and an inorganic material film was good, but a flash point was observed. In Comparative Examples 4 to 6 in which propylene glycol monomethyl ether acetate (PGMEA) was used, it was not dissolved in water, causing cloudiness, and so that use as a cleaning solution was impossible. Furthermore, in Comparative Examples 9 to 11 in which glycerine is as a main component, remaining of film with respect to a resist film and an inorganic material film was observed, showing that cleaning performance was short.

1. A cleaning solution for a semiconductor substrate or device, comprising a water-soluble organic solvent, quaternary ammonium hydroxide, and water, wherein the water-soluble organic solvent is a glycol ether solvent or an aprotic polar solvent having a flash point of 60° C. or more.

2. The cleaning solution according to claim 1, wherein the water-soluble organic solvent has a flash point of 60 to 150° C.

3. The cleaning solution according to claim 2, wherein the water-soluble organic solvent is at least one selected from the group consisting of 3-methoxy-3-methyl-1-butanol, diisopropylene glycol monomethyl ether, N-methyl-pyrrolidone, dimethyl sulfoxide, methyl diglycol, ethyl diglycol, and butyl diglycol.

4. The cleaning solution according to claim 2, wherein the water-soluble organic solvent is at least one selected from the group consisting of diisopropylene glycol monomethyl ether, N-methyl-pyrrolidone, and ethyl diglycol.

5. The cleaning solution according to claim 1, wherein the cleaning solution is used for cleaning a residue or a film formed on a semiconductor substrate or attached to a device, and including at least one selected from the group consisting of a resist and an inorganic substance that contains a silicon atom.

6. A cleaning method comprising cleaning a residue or a film from a semiconductor substrate or device, using the cleaning solution according to claim 1, wherein the residue or the film is formed on the semiconductor substrate or attached to the device, and includes at least one selected from the group consisting of a resist and an inorganic substance that contains a silicon atom.
